(19) United States
(12) Patent Application Publication
(10) Pub. No.: US 2026/0291180 A1
(43) Pub. Date: Sep. 24, 2026

(54) VERNIER-TUNED DISTRIBUTED BRAGG REFLECTOR LASER

(71) Applicant: Lumentum Operations LLC, San Jose, CA (US)

(72) Inventors: Michael C. LARSON, Oakland, CA (US); Duanhua KONG, Milpitas, CA (US)

(21) Appl. No.: 19/255,149

(22) Filed: Jun. 30, 2025

Related U.S. Application Data
(60) Provisional application No. 63/775,032, filed on Mar. 20, 2025.

(51) Int. Cl. H01S 5/12; H01S 5/125

(52) U.S. Cl. CPC H01S 5/1246; H01S 5/1209; H01S 5/125; H01S 2301/163

(57) ABSTRACT

In some implementations, a wavelength tunable semiconductor laser comprises a first mirror comprising a first integer number of repeat units, a second mirror comprising a second integer number of repeat units, and a gain section arranged between the first mirror and the second mirror. In some implementations, each of the first integer number of repeat units comprises a plurality of phase grating elements with a first plurality of pi phase shifts distributed among the plurality of phase grating elements, and each of the second integer number of repeat units comprises a plurality of phase grating elements with a second plurality of pi phase shifts distributed among the plurality of phase grating elements. The first plurality of pi phase shifts and the second plurality of pi phase shifts differ by one phase shift per repeat unit.

### CROSS-REFERENCE TO RELATED APPLICATION

This patent application claims priority to U.S. Provisional Patent Application No. 63/775,032, filed on Mar. 20, 2025, and entitled “VERNIER-TUNED DISTRIBUTED BRAGG REFLECTOR LASER.” The disclosure of the prior application is considered part of and is incorporated by reference into this patent application.

### TECHNICAL FIELD

The present disclosure relates generally to a tunable laser and to a wavelength-tunable semiconductor laser.

### BACKGROUND

A tunable laser is a laser with an emission wavelength that can be adjusted, often during operation. In some cases, a tunable laser may operate at a single frequency, where an emission linewidth is very narrow, corresponding to a well-defined wavelength. For example, for optical communication applications, a single mode or single frequency laser may be used with a large tuning range to cover an entire band. Other tunable lasers operate on multiple resonator modes simultaneously, such that an optical spectrum exhibits several or even many spectral lines. In such cases, wavelength tuning usually involves shifting an envelope of the optical spectrum. Wavelength-tunable lasers have various applications, such as optical fiber communications with wavelength division multiplexing where a tunable diode laser may be used as a spare laser in case a fixed-wavelength laser fails. In other examples, wavelength-tunable lasers can be used to record absorption spectra in laser absorption spectroscopy, to a wavelength specific to a certain substance to be monitored in a light detection and radar (LIDAR) system, or to adjust a laser wavelength precisely at or near some atomic resonance in a laser cooling system or laser isotope separation, among other examples.

### SUMMARY

In some implementations, a wavelength tunable semiconductor laser includes a first mirror comprising a first integer number of repeat units, wherein each of the first integer number of repeat units comprises a plurality of phase grating elements with a first plurality of pi phase shifts distributed among the plurality of phase grating elements; a second mirror comprising a second integer number of repeat units, wherein each of the second integer number of repeat units comprises a plurality of phase grating elements with a second plurality of pi phase shifts distributed among the plurality of phase grating elements; and a gain section arranged between the first mirror and the second mirror, wherein the first plurality of pi phase shifts and the second plurality of pi phase shifts differ by one phase shift per repeat unit.

In some implementations, an optical device includes a first distributed Bragg reflector (DBR) grating comprising a first plurality of repeat units, wherein the first plurality of repeat units each comprise a plurality of phase grating elements and a plurality of pi phase shifts, wherein: a number of phase grating elements is substantially the same in each of the plurality of repeat units of the first DBR grating, and a number or a location of the plurality of pi phase shifts is substantially the same in each of the plurality of repeat units of the first DBR grating; and a second DBR grating comprising a second plurality of repeat units, wherein the second plurality of repeat units each comprise a plurality of phase grating elements and a plurality of pi phase shifts, wherein: a number of phase grating elements is substantially the same in each of the plurality of repeat units of the second DBR grating, a number or a location of the plurality of pi phase shifts is substantially the same in each of the plurality of repeat units of the second DBR grating, and the number of the plurality of pi phase shifts in each of the first plurality of repeat units of the first DBR grating is different from the number of the plurality of pi phase shifts in each of the second plurality of repeat units of the second DBR grating.

In some implementations, a method includes generating light by a gain section of a wavelength tunable semiconductor laser; reflecting the light by a first mirror comprising a first integer number of repeat units, wherein each of the first integer number of repeat units comprises a plurality of phase grating elements with a first plurality of pi phase shifts distributed among the plurality of phase grating elements; and outputting a first portion of the light and reflecting a second portion of the light by a second mirror comprising a second integer number of repeat units, wherein each of the second integer number of repeat units comprises a plurality of phase grating elements with a second plurality of pi phase shifts distributed among the plurality of phase grating elements, wherein the first plurality of pi phase shifts and the second plurality of pi phase shifts differ by one phase shift per repeat unit.

### BRIEF DESCRIPTION OF THE DRAWINGS

FIG. 1 illustrates an example tunable semiconductor laser that includes a gain region between a pair of mirrors, and a filter disposed between the gain region and one of the mirrors.

FIG. 2 illustrates an example distributed Bragg reflector (DBR) laser and an example related to a tuning range for the DBR laser.

FIG. 3 illustrates an example sampled grating DBR laser, and examples indicating front and back mirror reflectivities and laser emissions at various wavelengths.

FIG. 4 illustrates an example related to a tuning range that may be determined according to a mirror peak spacing and a difference in front and back mirror spacings.

FIG. 5 illustrates examples related to a grating modulation function for an ideal comb-like reflector.

FIGS. 6A-6E illustrate examples of a Vernier-tuned DBR laser based on phase gratings with an improved supermode suppression manufacturing tolerance, in accordance with some implementations described herein.

FIG. 7 illustrates an example process for operating a wavelength tunable laser.

### DETAILED DESCRIPTION

The following detailed description of example implementations refers to the accompanying drawings. The same reference numbers in different drawings may identify the same or similar elements.

In various applications, such as telecommunications, a tunable laser should have a tuning range that satisfies a full communications bandwidth with a high side mode suppression ratio (SMSR). However, a tunable semiconductor laser formed only by an electrically-injected gain region patterned into an optical waveguide with cleaved and/or coated facets has a broad gain bandwidth that limits a capability to lase at a single frequency (or longitudinal mode). Instead, the laser cavity supports multiple longitudinal modes that are each associated with a corresponding resonant wavelength or frequency, and an optical wave that recirculates within the cavity adds constructively for each round trip. Accordingly, to select a single longitudinal (cavity) mode with a high SMSR, the laser cavity may incorporate a narrow-pass-band filtering element, such as a mirror that employs gratings etched into passive semiconductor waveguides to reflect only a narrow band of wavelengths, thus providing a filtering function and an optical reflection function in a single element. In such a laser design, the mirror that provides the combined filtering and optical reflection function includes a waveguide in which the grating is patterned, where the waveguide has a refractive index that can be tuned through carrier injection or Joule heating to position an optical reflectance band near one end of the tuning range. In addition to the mirror, the laser includes a gain section (where the light is generated) controlled by an electrical contact for current injection into an appropriately designed active region to provide optical gain and a phase section with a control terminal that allows fine tuning for the longitudinal mode spectrum. However, carrier injection or thermal tuning is physically unable to produce a sufficient refractive index shift to achieve full band tunability.

Accordingly, to overcome refractive index tuning limits, achieve full band tunability, and enable selection for a single longitudinal mode, a tunable laser may be designed with a laser cavity architecture with multiple cascaded filters. For example, the laser cavity architecture may include a gain section where the laser is generated, and front and back mirrors with grating patterns that are periodically spatially modulated in amplitude and/or phase to produce a comb-like multi-peaked reflectance spectrum, and the front and back mirrors have unequal repeat periods (lengths) to realize the Vernier effect (e.g., where currents applied to gratings with different periods can be varied to adjust the effective grating spacing and thereby achieve wide-range wavelength tuning with high precision). For example, the back mirror may be tuned (e.g., to shorter wavelengths) to achieve a large discrete jump to an adjacent set of mirror peaks through the Vernier effect, the front mirror may be tuned to achieve a jump to spectrum on a different supermode at a much longer wavelength, or both mirrors may be tuned in a synchronized fashion to tune any two mirror peaks together (on the same supermode) to select longitudinal modes between the wavelengths of the untuned mirror peaks. In this fashion, any mode can be selected by appropriate combination of differential and synchronized tuning, and with additional phase tuning, any arbitrary target wavelength can be achieved.

Although the Vernier effect enables an enhanced (full-band) tuning range, the Vernier effect is constrained in practice because the spectral comb spacing difference between the front mirror and the back mirror has to be large enough compared to the spectral width of individual mirror peaks to attenuate the spectral overlap of side supermodes which would otherwise degrade SMSR. In addition, a comb-like mirror spectrum produces a repeat mode, where two pairs of peaks are simultaneously aligned at opposite ends of the tuning range, with an associated repeat mode spacing that serves as an upper bound on the tuning range. To eliminate the repeat mode effect, a finite number of mirror peaks are desired such that the peak spacing multiplied by the number of peaks is less than the repeat mode spacing. This is not practically realizable with a sampled grating, however, because a rectangular sampling function produces a comb-like spectrum modulated by a sinc-like spectral envelope. On the other hand, phase gratings may be used instead of sampled gratings to provide greater degrees of freedom in designing the reflection spectrum of the grating, where optimizing the number and placement of phase shifts can approximate a spectral envelope that reduces undesired peaks by more than twofold. However, the phase grating approach has several shortcomings when applied in a Vernier tuned laser, including challenges to independently control peak reflectance and spectral width in the front mirror versus the back mirror and to eliminate peaks outside the desired tuning range.

In some implementations, as described herein, a wavelength tunable semiconductor laser has a design that eliminates a repeat mode where a first pair of front mirror and back mirror peaks and a second pair of front mirror and back mirror peaks, on opposite ends of a tuning range, are simultaneously aligned. For example, in some aspects, the wavelength tunable semiconductor laser includes a gain section, a front mirror that includes a first integer number of repeat units, and a back mirror that includes a second integer number of repeat units. In some implementations, the first integer number of repeat units includes a first set of phase grating elements (where each phase grating element includes an etched region paired with an unetched region) with a first plurality of pi phase shifts distributed among the first set of phase grating elements, and the second integer number of repeat units includes a second set of phase grating elements with a second plurality of pi phase shifts distributed among the second set of phase grating elements. In some implementations, the first plurality of pi phase shifts differs from the second plurality of pi phase shifts by one phase shift per repeat unit (e.g., where a phase shift is realized with an etched region or an unetched region with a length that differs from a phase grating without a phase shift). Furthermore, in some implementations, the first integer number of repeat units differs from the second integer number of repeat units. In some implementations, the phase grating elements of the front mirror are configured to produce a first comb reflection spectrum and a second comb reflection spectrum, each of which includes a plurality of reflection peaks that are substantially within a target spectral envelope (e.g., approximating a top-hat spectral envelope, with some allowed structure under the target spectral envelope to compensate for a gain envelope). Furthermore, any peaks that are outside the target spectral envelope are decreased relative to peaks within the target spectral envelope by a desired percentage or ratio.

In this way, by eliminating the repeat mode where mirror peaks on opposite ends of a tuning range are simultaneously aligned, some implementations described herein enable an improved manufacturing tolerance and spectral purity for a wavelength tunable semiconductor laser. For example, some implementations described herein eliminate the repeat mode that may otherwise result in the gain spectrum determining the actual wavelength range, which would make channel coverage highly sensitive to the material composition of the active (gain) region. Furthermore, by providing a target spectral envelope approximating a top-hat structure, some implementations described herein produce mirror reflectivity peaks outside the desired tuning band that drop off to near zero on two orders. Furthermore, some implementations described herein enable the mirror reflectivity peaks to be adjusted by omitting one or more gratings from the repeat units, with no change on the envelope associated with the reflectivity peaks, such that the front mirror and the back mirror can be fabricated in a single etch step, and allow a mixed number of peaks to be employed while zeroing out any unwanted peaks on the short side and long side of the tuning range, providing substantial improvements in sensitivity to gain spectrum.

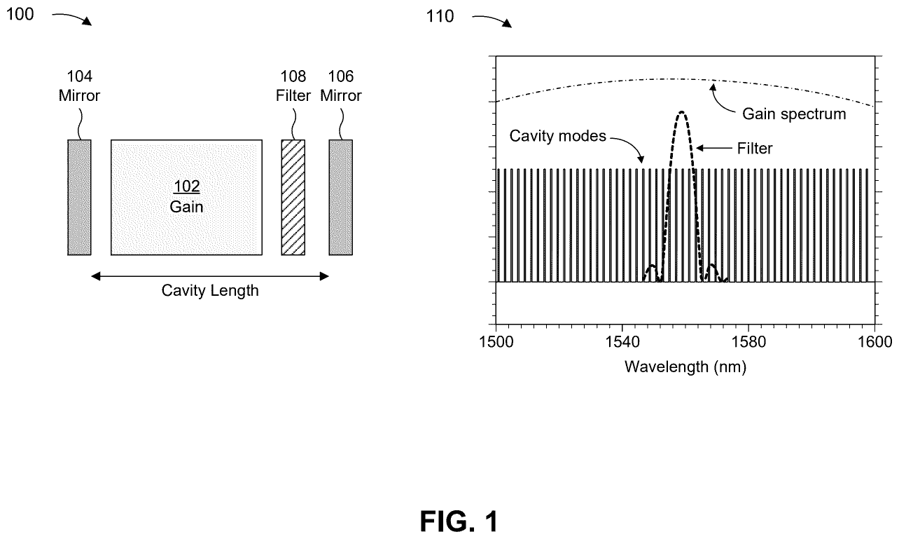

FIG. 1 illustrates an example tunable semiconductor laser 100. As shown in FIG. 1, the tunable semiconductor laser 100 includes a gain region 102 arranged between a first mirror 104 and a second mirror 106, and a filter 108 disposed between the gain region 102 and the second mirror 106. The tunable semiconductor laser 100 is formed from the gain region 102, which is electrically-injected and patterned into an optical waveguide with cleaved and/or coated facets. For example, a laser generated within the gain region 102 is reflected by the second mirror 106, where a laser cavity (e.g., a region between the first mirror 104 and the second mirror 106) provides feedback that allows specific wavelengths to amplify and lase. Furthermore, to make the laser 100 tunable, a resonance or gain peak within the cavity is adjustable (e.g., via electrical tuning and thermal tuning to change the carrier density in different sections to modify a refractive index of the semiconductor waveguide and thereby alter an effective cavity optical length).

However, monolithically-integrated tunable lasers (e.g., for telecommunications or other suitable applications) are typically designed to have a tuning range that satisfies a full communications bandwidth (e.g., greater than 40 nanometers (nm) in the C-band near a 1550 nm wavelength, or greater than 48 nm for extended band), with a SMSR (e.g., more than 40 decibels (dB)). In a semiconductor laser formed only by an electrically-injected gain region, such as the laser shown in FIG. 1, a gain bandwidth has a breadth that prevents the semiconductor laser from having the capability to lase at a single frequency (or single longitudinal mode). Instead, the laser cavity supports multiple longitudinal modes, each with a corresponding resonant wavelength and frequency, for which a recirculating optical wave adds constructively for each round trip. In other words, the propagated round-trip phase within the laser cavity is equal to an integer multiple of 2π. To select a single longitudinal (cavity) mode with a high SMSR, the laser cavity incorporates a narrow-pass-band filtering element, shown in FIG. 1 by the filter 108 disposed between the gain region 102 and the second mirror 106.

For example, when a laser generated within the gain region 102 circulates within the laser cavity between the first mirror 104 and the second mirror 106, any given longitudinal mode is associated with a lasing threshold oscillation condition or unity round trip gain given by:

$${r}_{1} {r}_{2} F ( λ ) {e}^{- 2 j β L + ( 〈 {g}_{th} 〉 - {α}_{i} ) L} = 1$$

where r₁, r₂ is a complex mirror reflectivity, F is a round-trip filter transmission, λ is a free space wavelength, <gₜₕ> is a threshold modal gain, αᵢ is a waveguide loss, β=2πn_{eff}/λ, and n_{eff} is a waveguide effective refractive index. The wavelength corresponds to an integral multiple of 2π round trip phase, and the threshold modal gain corresponds to a unity round trip gain magnitude. The filter 108 has a high transmittance at an intended lasing mode (and thereby a low threshold gain), and has to be narrow enough to select a single cavity mode while simultaneously exhibiting reduced transmittance (or high loss) at all other longitudinal modes. As a result, the precise lasing wavelength is determined according to the cavity (longitudinal) mode, and the threshold gain of unintended sidemodes is increased by a sufficient degree for high SMSR. For example, as shown by example plot 110, the laser cavity generates many longitudinal modes with different resonant wavelengths within a gain spectrum, and the filter 108 is tuned to select a single longitudinal mode with a high SMSE (e.g., depending on a physical realization, the filter 108 may be thermally, mechanically, and/or electronically tuned).

As indicated above, FIG. 1 is provided as an example. Other examples may differ from what is described with regard to FIG. 1.

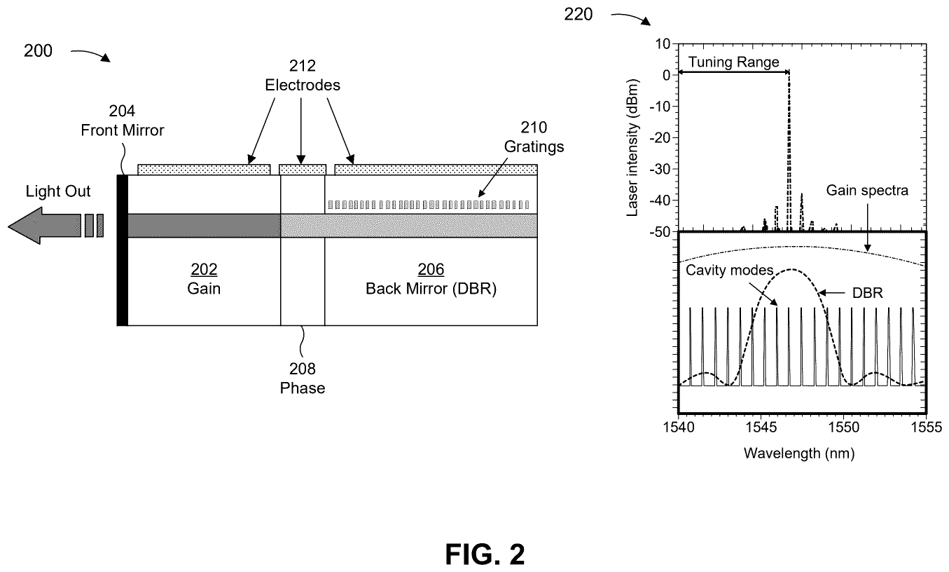

FIG. 2 illustrates an example distributed Bragg reflector (DBR) laser 200 and an example 220 related to a tuning range for the DBR laser 200. In particular, as described herein, a DBR laser 200 employs gratings 210 etched into a passive semiconductor waveguide to reflect only a narrow band of wavelengths, thus providing both a filtering function and an optical reflection function in one element. For example, the DBR laser 200 shown in FIG. 2 includes a back mirror 206 implemented as a DBR (e.g., via the gratings 210) to combine filtering and reflection functions, and a front mirror 204 that is an etched facet with a fixed broadband reflectance (e.g., enhanced with an appropriate dielectric coating to adjust the reflectance for optimum output coupling). The DBR (or back mirror) 206 has a tuning electrode 212 that can be used to adjust the refractive index of one or more layers of a semiconductor waveguide of the DBR 206, either through carrier injection or Joule heating.

In this way, the effective index of the waveguide in which the gratings 210 are patterned can be tuned. The pitch of the gratings 210 is chosen in order to position the optical reflectance band near one end of the desired tuning range such that the optical reflectance band can be tuned to shorter wavelengths (e.g., if carrier injection is employed) or tuned to longer wavelengths (e.g., if thermal tuning is used) by a controllable amount. In addition to the DBR 206, the DBR laser 200 includes a gain section 202 controlled by an additional electrode 212 for current injection into an appropriately designed active region to provide optical gain. The DBR laser 200 includes a phase section 208 with an electrode 212 providing a control terminal to fine tune the longitudinal mode spectrum. However, carrier injection or thermal tuning cannot produce a sufficient refractive index shift to achieve full band tunability (e.g., single-side DBR lasers typically achieve at best a tuning range from 12-15 nm, as shown by example 220).

As indicated above, FIG. 2 is provided as an example. Other examples may differ from what is described with regard to FIG. 2.

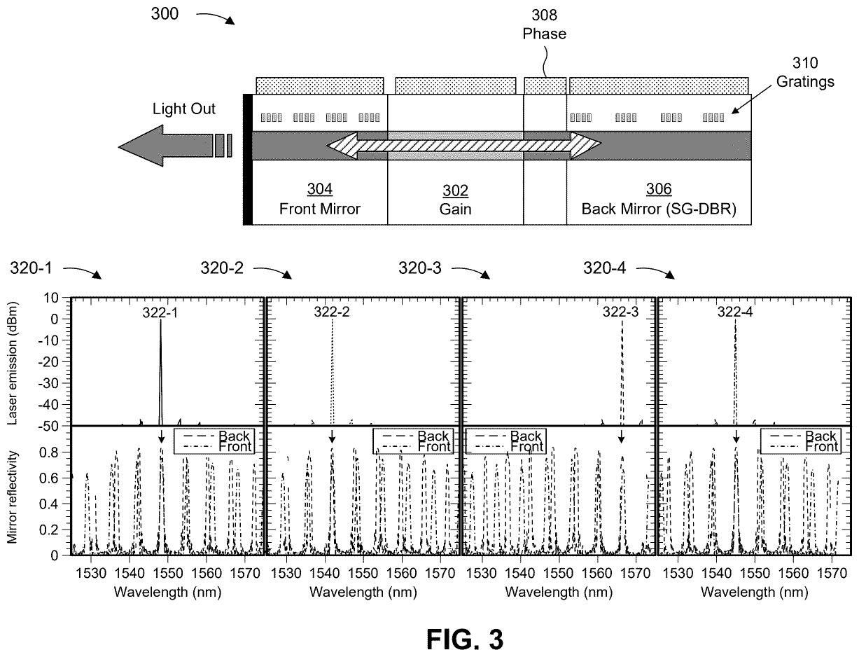

FIG. 3 illustrates an example sampled grating DBR (SG-DBR) laser 300, and examples 320 indicating front and back mirror reflectivities and laser emissions at various wavelengths. For example, a laser cavity architecture with multiple cascaded filters may use the Vernier effect to overcome refractive index tuning limits and achieve full band tunability while still selecting for a single longitudinal mode. The SG-DBR laser 300 has a four-section laser cavity architecture that uses the Vernier effect, where the laser cavity architecture includes a gain region 302 controlled by an electrode for current injection to provide optical gain, a front DBR mirror 304 and a back DBR mirror 306 with etched gratings 310, and a phase region 308 with an electrode providing a control terminal to fine tune the longitudinal mode spectrum. However, the gratings 310 in the front DBR mirror 304 and the back DBR mirror 306 have patterns that are periodically and spatially modulated in amplitude and/or phase to produce a comb-like multi-peaked reflectance spectrum. Furthermore, a repeat period (or length) in the front mirror 304 and the back mirror 306 are unequal, to realize the Vernier effect.

In the SG-DBR laser 300, the gratings 310 follow a grating function that is periodically sampled (or conversely, blanked). For example, as shown in FIG. 3, the front DBR mirror 304 and the back DBR mirror 306 are each formed by short bursts of gratings 310 separated by longer blank regions (e.g., as though a spatially uniform grating 310 were multiplied by a periodic rectangular sampling function of a fixed repeat period, hence the basis for the “sampled grating” terminology). The untuned spectra of the front mirror 304 and the back mirror 306 are shown by example 320-1, where only the two middle peaks are aligned due to the unequal comb spacings. Furthermore, the combination of aligned mirror peaks is known as a supermode. The combined (multiplied) filter spectrum for the supermode selects a single longitudinal mode corresponding to the lasing spectrum labelled with reference number 322-1 in example 320-1. By tuning the back mirror 306 (e.g. to shorter wavelengths), a large discrete jump to an adjacent set of mirror peaks (a neighboring supermode) is achieved through the Vernier effect, as shown by the lasing spectrum labelled with reference number 322-2 in example 320-2. Likewise, tuning the front mirror 304 alone can result in a jump to the lasing spectrum labelled with reference number 322-3 in example 320-3 on a different supermode at a much longer wavelength. Finally, tuning both the front mirror 304 and the back mirror 306 in a synchronized fashion allows for any two mirror peaks to be tuned together (on the same supermode) to select longitudinal modes in between the wavelengths of the untuned mirror peaks, as shown by the lasing spectrum labelled with reference number 322-4 in example 320-4. In this way, any mode can be selected by an appropriate combination of differential and synchronized tuning, and any arbitrary target wavelength can be achieved with the addition of phase tuning.

As indicated above, FIG. 3 is provided as an example. Other examples may differ from what is described with regard to FIG. 3.

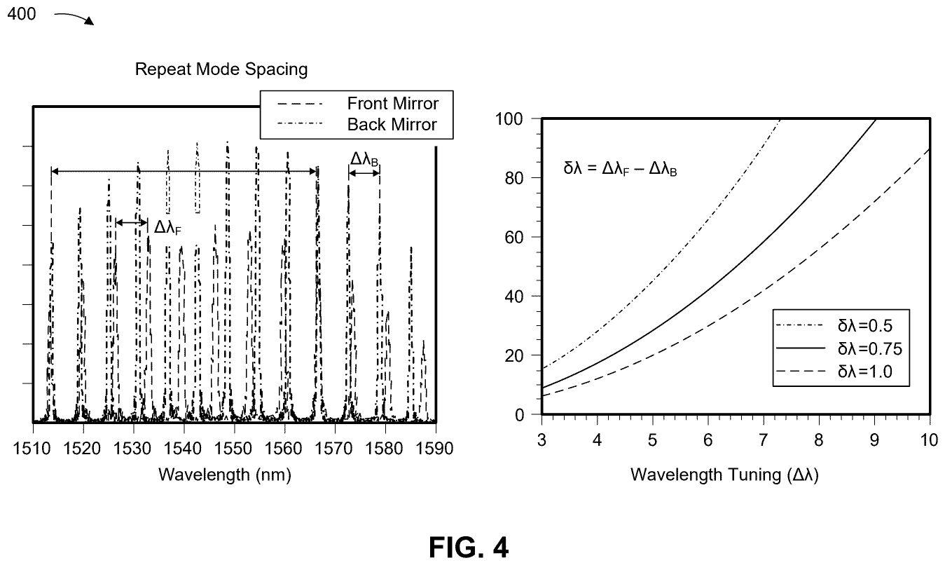

FIG. 4 illustrates an example 400 related to a tuning range that may be determined according to a mirror peak spacing and a difference in front mirror and back mirror spacings in a laser cavity architecture that uses the Vernier effect, such as the SG-DBR laser 300 shown in FIG. 3. Although the Vernier effect enables an enhanced (full-band) tuning range, the Vernier effect is practically constrained. For example, a spectral comb spacing difference between the front mirror and the back mirror may be denoted δλ=Δλ_{F}−Δλ_{B}, where Δλ_{F} is a spacing between peaks of the front mirror and Δλ_{B} is a spacing between peaks of the back mirror. In general, the spectral comb spacing difference between the front and back mirrors has to be large enough, compared to the spectral width of individual mirror peaks, to attenuate a spectral overlap of side supermodes that would otherwise degrade the SMSR. In addition, a comb-like mirror spectrum generally produces a repeat mode, whereby a first pair of peaks is aligned at one end of the tuning range and a second pair of peaks is aligned at the opposite end of the tuning range, with an associated repeat mode spacing (RMS), as shown by example 400.

As described herein, the RMS value, equal to (Δλ_{F}Δλ_{B})/(Δλ_{F}−Δλ_{B}), is an upper bound on the tuning range for a laser cavity architecture that uses the Vernier effect. Because the two competing supermodes are spectrally distant, the gain spectrum, in combination with the mirror spectral envelopes, determines whether the shorter wavelength or the longer wavelength has the lowest threshold and becomes the dominant lasing supermode. In some cases, the gain spectrum shape exactly counterbalances the mirror peak reflectance, neither supermode is dominant, and the laser exhibits poor SMSR and therefore a reduction in effective tuning range. The net effect is that Vernier tuning places stringent manufacturing tolerances on active region material composition and layer thickness to achieve the required repeatability in gain spectrum. If the gain spectrum is unintentionally shifted due to manufacturing variation, the resulting tuning range may fail to satisfy a channel plan constraint. Alternatively, the laser may be overdesigned in tuning range by 20% or more to accommodate the variation in gain spectrum, at the expense of additional tuning power dissipation or other design compromises.

As indicated above, FIG. 4 is provided as an example. Other examples may differ from what is described with regard to FIG. 4.

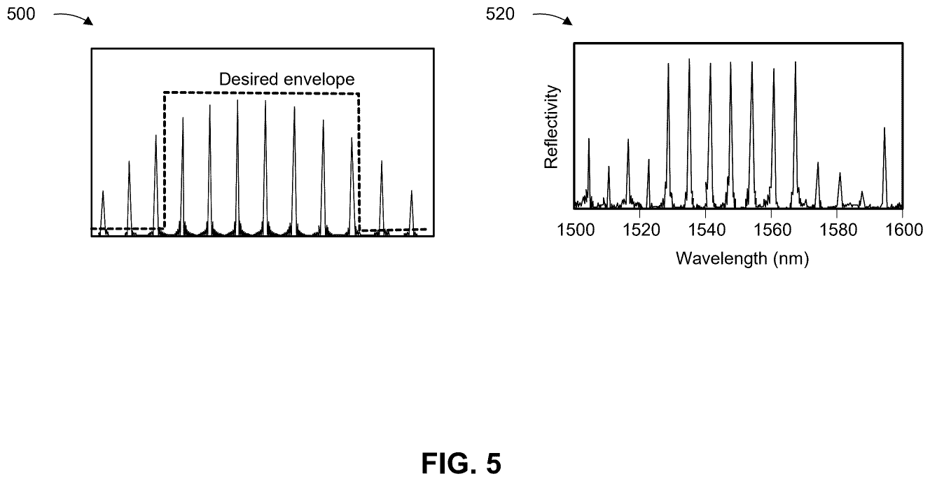

FIG. 5 illustrates examples 500 and 520 related to a grating modulation function for an ideal comb-like reflector. To eliminate the repeat mode effect described above, a finite number of mirror peaks are desired such that the peak spacing times the number of peaks is less than the repeat mode spacing, which is not practically realizable with a sampled grating (e.g., because a rectangular sampling function produces a comb-like spectrum modulated by a sinc-like spectral envelope). On the other hand, a phase grating provides an approach to engineer the reflectance spectrum. Accordingly, some implementations described herein relate to a wavelength tunable semiconductor laser that uses a phase grating rather than a sampled grating, where the phase grating provides greater degrees of freedom in designing the reflection spectrum of the grating. The phase grating starts with a uniform grating that undergoes an inversion in tone (or π phase shift) at multiple locations within a repeat unit, which is a section of the overall grating. For instance, as described herein, a sequence of alternating masks (M) and spaces (S) represents one repeat unit, where each mask is an unetched region and each space is an etched region, and a phase shift may be realized in a phase grating with a mask or a space that has a length that is double the length of a mask or space in a phase grating without a phase shift. The entire grating includes multiple repeat units (e.g., on the order of 5 to 15 repeat units) concatenated together. The repeat unit has a length known as a repeat length.

In some implementations, the number and placement of the phase shifts may be optimized to approximate a top-hat spectral envelope of near equal reflectance peaks, as shown in example 500. Alternatively, as shown by example 520, a fixed number of peaks (e.g., seven in example 520) with a relatively uniform spectral envelope can be achieved with a phase-shifted grating, with undesired peaks reduced by greater than twofold. For example, the phase-shifted grating is a uniform grating with π phase shifts introduced at appropriate locations, and a design of the phase-shifted grating may be optimized using numerical techniques. In addition, appropriate techniques may be used to optimize for an enhanced reflectance of the outer peaks and a reduced reflectance of the middle-band peaks to compensate for the gain spectrum shape.

However, the phase grating approach has shortcomings when applied to Vernier-tuned lasers. For example, independent control of peak reflectance and spectral width in the front mirror versus the back mirror is challenging unless the grating strength (grating corrugation depth) is independently controlled in the two DBRs. In particular, the front mirror has a lower peak reflectance than (less than half) the peak reflectance of the back mirror to achieve high front facet slope efficiency, which may be addressed by combining a sampled grating front mirror with a superstructure or phase grating back mirror. In addition, peaks outside the required tuning range should approach zero.

As indicated above, FIG. 5 is provided as an example. Other examples may differ from what is described with regard to FIG. 5.

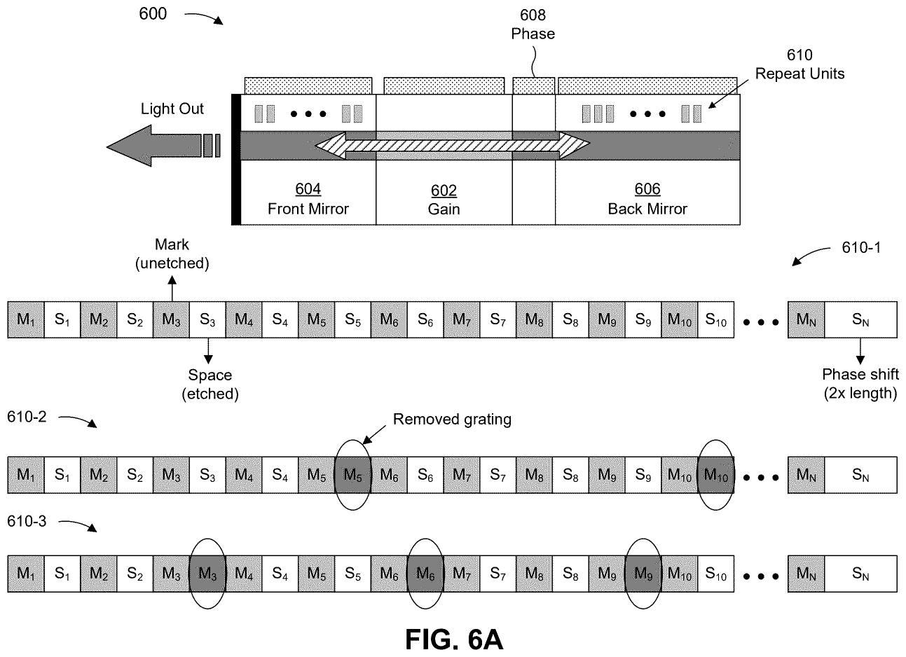

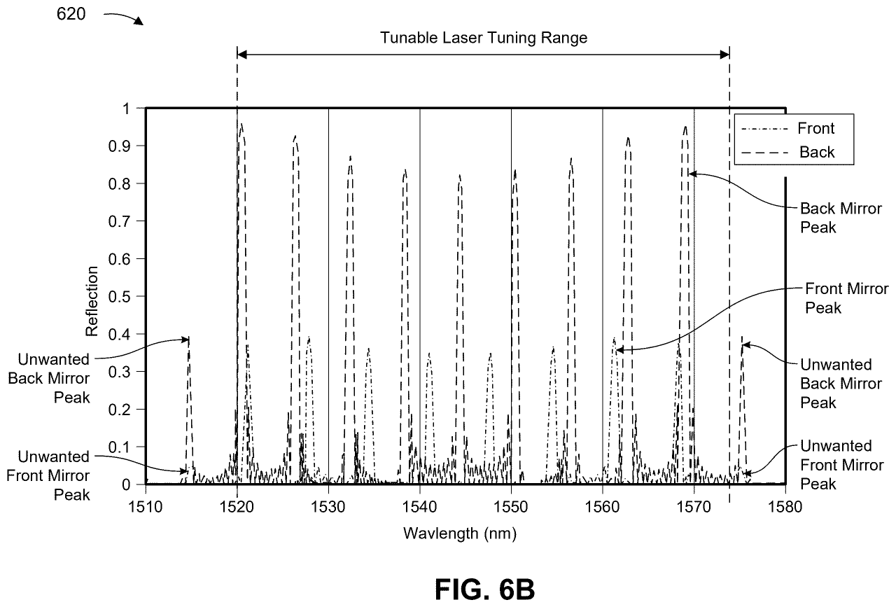

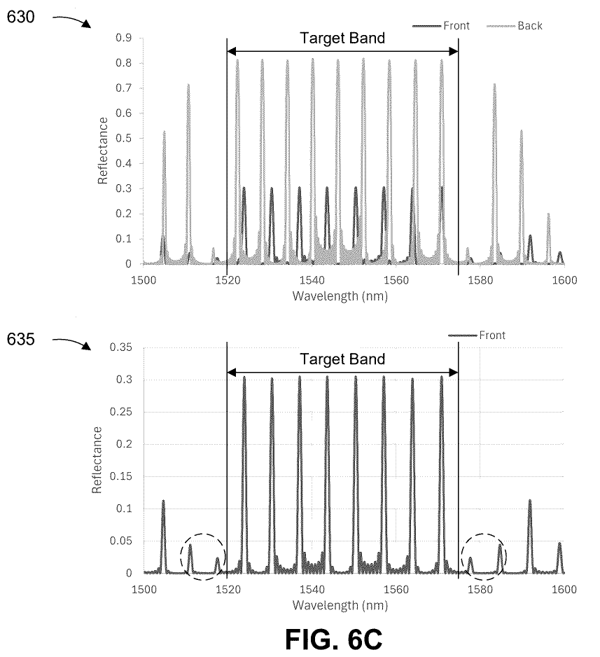

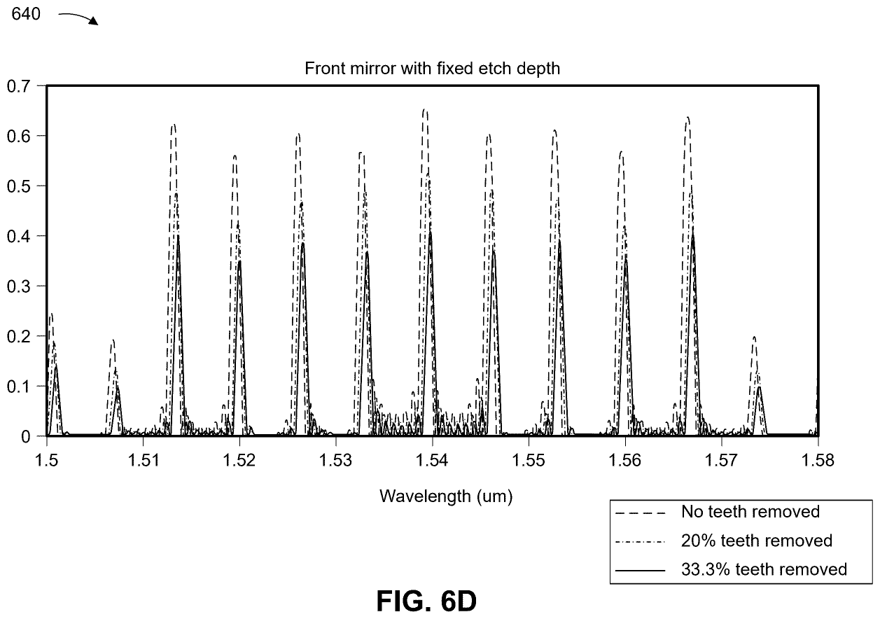

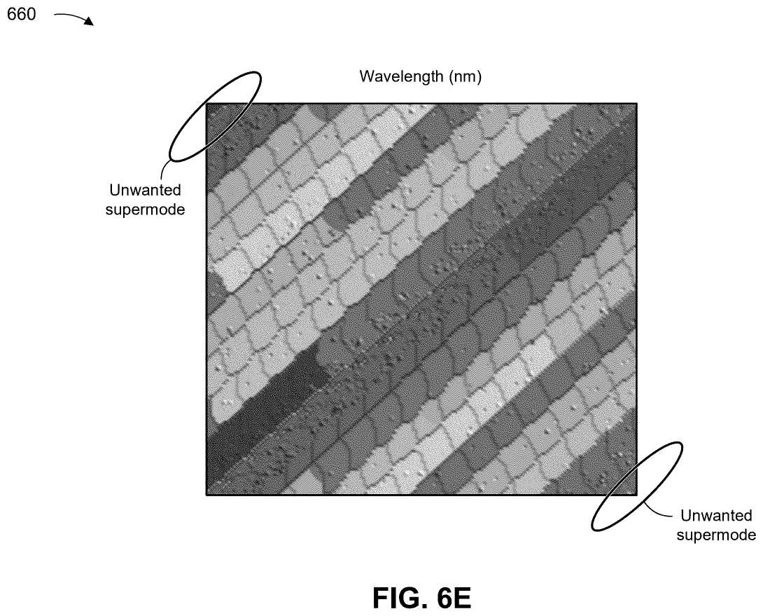

FIG. 6A illustrates an example Vernier-tuned DBR laser 600, which is a wavelength tunable semiconductor laser based on phase gratings with an improved supermode suppression manufacturing tolerance, in accordance with some implementations described herein. In addition, FIG. 6B illustrates an example tuning range 620 for the Vernier-tuned DBR laser 600, FIG. 6C illustrates example reflectances 630 and 635 within and outside a target spectral envelope, FIG. 6D illustrates an example comb reflection spectrum 640 generated by the Vernier-tuned DBR laser 600, and FIG. 6E illustrates an example wavelength map 660 for the Vernier-tuned DBR laser 600. More particularly, to improve manufacturing tolerance and spectral purity, the Vernier-tuned DBR laser 600 is designed to eliminate the repeat mode described above, where a first pair of front and back mirror peaks are aligned on a first end of a tuning range and a second pair of front and back mirror peaks are aligned on an opposite end of the tuning range. When the repeat mode is present, the gain spectrum determines the actual wavelength range, which makes channel coverage highly sensitive to the material composition of the active region.

Accordingly, the Vernier-tuned DBR laser 600 is implemented to eliminate the repeat mode with a wavelength tunable semiconductor laser structure that includes a gain section 602, a front mirror 604 with a first integer number of repeat units 610, and a back mirror 606 with a second integer number of repeat units 610. In some implementations, the first integer number of repeat units 610 may include phase grating elements with a first plurality of π phase shifts distributed among the phase grating elements, and the second integer number of repeat units 610 may include phase grating elements with a second plurality of π phase shifts distributed among the phase grating elements. As described herein, the term “phase grating element” refers to one mask (corresponding to an unetched region or a region with unetched material) paired with one space (corresponding to an etched region or a region with etched material).

For example, in FIG. 6A, reference numbers 610-1, 610-2, and 610-3 each depict one repeat unit 610, which includes N phase grating elements that each include a mask denoted Mᵢ paired with a space denoted Sᵢ. Furthermore, a phase grating element with a phase shift is realized with a mask or a space that has a length that is double the length of a mask or space of a phase grating element without a phase shift. For example, in the repeat units 610 depicted by reference numbers 610-1, 610-2, and 610-3, a phase shift is present at the Nth phase grating, where the space SN has a larger length than the length of the spaces in the first ten phase gratings. For example, as described herein, a pitch is defined by the combined length of one mask and one space, and a phase shift is equal to half the pitch (e.g., the spaces where the phase shifts are present have a length that is twice the length of the other spaces when the masks and spaces have the same length, or a mask: space ratio is equal to 1). Furthermore, there may be additional phase shifts at other locations within a given repeat unit (e.g., in a repeat unit 610 with 209 phase gratings, there could be six phase shifts distributed at different locations among the 209 phase gratings). In some implementations, the first plurality of π phase shifts and the second plurality of π phase shifts differ by one phase shift per repeat unit. As described herein, a π phase shift is equivalent or similar to a 180-degree phase shift, where a wave is inverted such that a position and direction of the wave is inverted where the phase shift occurs.

In some implementations, as shown in FIG. 6A, the wavelength tunable semiconductor laser structure may further include a phase section 608 with a control terminal where current can be injected to fine tune the longitudinal mode spectrum. In some implementations, the integer number of repeat units 610 in the front mirror 604 differs from the integer number of repeat units 610 in the back mirror 606. For example, adding more repeat units 610 generally increases the reflectance of each peak and narrows the spectral width of each peak, while maintaining similar relative envelope. To direct most of the laser emission out the front facet, some implementations may include fewer repeat units 610 in the front mirror 604 and more repeat units 610 in the back mirror 606. However, there is no specific constraint on the difference between the integer number of repeat units 610 in the front mirror 604 and the integer number of repeat units 610 in the back mirror 606, except that a sufficient number of repeat units 610 are used as to produce a sufficiently narrow spectral filter function of the product of the front mirror 604 and the back mirror 606 to select a single longitudinal mode. In some implementations, the mirror with the larger peak spacing, and therefore the shorter repeat length, may have one less phase shift per repeat unit relative to the mirror with the smaller peak spacing or longer repeat length. In some implementations, the front mirror 604 may be modified by removing a subset of the phase grating elements (e.g., replacing an etched region or space with unetched material).

For example, referring to FIG. 6A, reference numbers 610-1, 610-2, and 610-3 provide example grating definitions (or configurations) for the phase grating elements in a repeat unit 610, where each phase grating element includes a mask corresponding to an unetched region paired with a space corresponding to an etched region, where the masks and spaces with a phase shift are double length. For example, in FIG. 6A, elements labelled Mᵢ and Sᵢ form an i^{th} phase grating element (e.g., the elements labelled M₁ and S₁ form a first phase grating element, the elements labelled M₂ and S₂ form a second phase grating element, and so on). In FIG. 6A, reference number 610-1 depicts a repeat unit 610 with a grating definition in which all of the gratings are maintained. Reference number 610-2 depicts a repeat unit 610 with a grating definition in which 20% of the gratings ae removed (e.g., every fifth grating is removed, as shown by circled unetched regions M₅ and M₁₀ replacing etched regions S₅ and S₁₀, respectively), and reference number 610-3 depicts a repeat unit 610 with a grating definition in which 33.3% of the gratings are removed (e.g., every third grating is removed). Accordingly, as described herein, removing a grating (or replacing an etched region with unetched material) results in three consecutive unetched regions (e.g., at the location where the grating is removed, plus the two unetched regions that are adjacent to the removed grating).

As described herein, one mirror in the Vernier-tuned DBR laser 600 (e.g., the mirror one with a larger comb spacing, typically the front mirror 604) has one less mirror peak than the other mirror, with no reduction in tuning range. As shown by example 620 in FIG. 6B, the tunable laser tuning range includes nine mirror peaks for one mirror in the Vernier-tuned DBR laser 600 (e.g., the back mirror 606 in the illustrated example), and eight mirror peaks for the other mirror (e.g., the front mirror 604 in the illustrated example). To reduce the number of mirror peaks, and thereby mitigate the repeat mode effect, the front mirror 604 is designed to have one less phase shift than the back mirror 606 (and therefore an odd total number of phase shifts per repeat unit 610 in the front mirror 604 to produce an even number of mirror peaks). In contrast, conventional designs are restricted to an even number of shifts (and therefore an odd number of mirror peaks) such that the middle peak wavelength substantially matches a conventional uniform grating.

In some implementations, the Vernier-tuned DBR laser 600 uses a mirror design with a spectrum envelope in which mirror reflectivity peaks outside a required tuning band drop off to near zero, or by at least five fold (e.g., more than 10 dB reduction compared to in-band), on two orders. For example, the envelope may be similar to the top-hat envelope shown by example 500 in FIG. 5, which may be achieved with an odd number of shifts per repeat unit (e.g., as shown by the spectrum of the front mirror 604 in example 620). In some implementations, the spectrum envelope may include some structure under the envelope to compensate for a gain envelope. For example, according to some implementations, the phase grating elements of the front mirror 604 may be configured to produce a first comb reflection spectrum with a first plurality of reflection peaks substantially within a target spectral envelope. In some implementations, the phase grating elements of the back mirror 606 may be configured to produce a second comb reflection spectrum with a second plurality of reflection peaks substantially within the target spectral envelope. In some implementations, the first plurality of reflection peaks has one less peak than the second plurality of reflection peaks (e.g., in example 620, the back mirror 606 produces 9 reflection peaks, and the front mirror produces 8 reflection peaks). In some implementations, peaks outside the target envelope may be decreased by a desired percentage, such as least five fold, relative to peaks within the envelope (e.g., as shown by the height of the unwanted peaks produced by the front mirror 604 and the back mirror 606 in example 620 relative to the peaks of the front mirror 604 and the peaks of the back mirror 606 that fall within the laser tuning range). In some implementations, a structure of the peaks within the envelope (e.g., within the laser tuning range) may compensate for the material-based spectrum of the gain region 602.

For example, FIG. 6C illustrates example reflectances 630 within and outside a target spectral envelope for the front mirror 604 and the back mirror 606, where the two peaks that are outside and immediately adjacent to the low side of the target band and the two peaks that are outside and immediately adjacent to the high side of the target band are reduced by at least five fold relative to the peaks that are within the target band. For example, example reflectances 630 are shown for the front mirror 604 and the back mirror 606 within a target band that ranges from 1520-1575 nm, and example reflectances 635 within the target band are shown in more detail for the front mirror 604 only. In the example reflectances 635, the two peaks that are outside and immediately adjacent to the low side of the target band and the two peaks that are outside and immediately adjacent to the high side of the target band are enclosed within dashed circles. As shown, the peak reflectance of the front mirror 604 is about 30% within the target band, the first pair of peaks that are outside and immediately adjacent to the target band have a reflectance of about 2.4%, and the second pair of peaks that are outside and immediately adjacent to the target band have a reflectance of about 4.4%. Accordingly, the first pair of peaks and the second pair of peaks outside the target band easily satisfy the five fold condition. Although the third pair of peaks outside the target band has a higher reflectance, the higher reflectance is unimportant, because the gain spectrum is not sufficiently wide to allow the third pair of peaks (or other peaks farther from the target band) to compete with the peaks that are within the target band. Accordingly, as described herein, the first pair of peaks outside the target band and immediately adjacent to the target band are smaller than the peaks within the target band by at least five fold, and the second pair of peaks outside the target band and immediately adjacent to the target band are preferably also smaller than the peaks within the target band by at least five fold.

In some implementations, because mirror reflectivity peaks can be adjusted by eliminating part of the gratings, with no change on the envelope of reflectivity peaks, the front mirror 604 and the back mirror 606 of the Vernier-tuned DBR laser 600 can be fabricated with a single etch step. In some implementations, the Vernier-tuned DBR laser 600 may have a design that simultaneously employs a mixed number of peaks (e.g., eight and nine) and zeroes out the two unwanted peaks on both the short side of the tuning range and the long side of the tuning range, which can substantially improve sensitivity to gain spectrum.

According to some implementations, the Vernier-tuned DBR laser 600 may use a grating design to mitigate or eliminate grating teeth. In some implementations, a desired reflection spectrum may be designed by iteratively modeling the reflection for a concatenated set of repeat units 610. The parameters that can be adjusted (for a given etch depth) may include the number of grating elements (masks and spaces), the number of repeat units 610, the number of phase shifts, the location of the phase shifts, the location of removed grating elements, and/or the number of removed grating elements. For example, the grating (or mirror) may have a pitch in a range from 0.2 to 0.3 micrometers (μm), where the pitch is determined by dividing a wavelength by twice the waveguide refractive index where the pitch is the length of one mask plus one space. The reflection spectrum of the grating can be adjusted by introducing phase shifts into the grating. For example, a phase shift may be introduced by doubling the length of a space or a mask in the grating. Each grating may include a number of phase shifts in a range from 1 to 20. The total length of the repeat units may be in a range from 1 to 100 μm, and may be determined by multiplying the pitch by the sum of the number of masks/spaces plus half of the number of phase shifts, and the number of repeat units may be in a range from 2 to 30. The etch depth (e.g., for a space) is a parameter that describes how deeply the space is etched into the waveguide, and the strength of the grating (how much light is reflected per unit length) is another design parameter. For example, the grating strength parameter may be adjusted by adjusting the grating etch depth. The front mirror 604 and the back mirror 606 may have different reflectivities and different grating strengths, whereby the front mirror 604 and the back mirror 606 have different etch depths. Alternatively, reflectivities can be controlled by eliminating part of the gratings on one mirror (e.g., the front mirror 604), in which case the front mirror 604 and the back mirror 606 can have the same etch depth.

In some implementations, the number of repeat units 610 and the number of removed grating elements may determine the total reflectivity of the mirror and the width of the reflectivity peaks. As described elsewhere herein, the front mirror 604 may be designed to have less reflection than the back mirror 606 in order to couple light out of the laser cavity. The number of main comb peaks in the spectrum may be determined by the number of phase shifts. The front mirror 604 and the back mirror 606 are designed with different numbers of phase shifts and therefore have different numbers of main comb peaks. The number of peaks in each comb and the peak spacing are determined by the desired tuning range of the laser 600. In some implementations, the number and locations of phase shifts determine the overall spectral shape. For example, the number and locations of phase shifts can determine how quickly the reflection intensity drops off outside of the desired range, as shown by example 640 in FIG. 6D by the lower peaks on the left and right sides. These parameters can also adjust the overall outline shape for the spectrum (e.g., as shown by example 500 in FIG. 5). As further shown by example 640 in FIG. 6D, the center part of the comb spectrum drops in the middle, which can be an intentional adjustment to compensate for the peak in the gain spectrum of the laser material (e.g., as shown by the gain spectrum curve in example plot 110 in FIG. 1). The number of removed teeth determines the overall spectral peak reflectivity (e.g., as shown by example 640, where mirror peak reflectivity varies with grating removal, with a highest peak reflectivity where no gratings are removed and a lowest peak reflectivity where 33.3% of the gratings are removed). In some implementations, the gratings may be removed periodically (e.g., every n^{th} grating is removed). Alternatively, the gratings may be removed randomly, which may introduce more loss for the grating compared to periodic grating removal.

Referring to FIG. 6E, example 660 illustrates a wavelength map for the Vernier-tuned DBR laser 600 in a design where the front mirror 604 has eight peaks and the back mirror 606 has nine peaks. For example, unwanted peaks on both the short and the long side of the tuning range are more than 3 dB lower than the peaks inside the tuning range, and unwanted supermodes moved to the top-left or bottom-right of the wavelength map do not occupy the dominated supermodes area. In this way, sensitivity to gain spectrum is substantially improved. The front mirror 604 (e.g., with five total phase shifts per repeat unit 610) with the larger peak spacing and therefore the shorter repeat length has one less phase shift per repeat unit 610 than the back mirror 606 (e.g., six total phase shifts per repeat unit) with the smaller peak spacing or longer repeat length.

In some implementations, the Vernier-tuned DBR laser 600 may include non-identical repeat units 610 that are substantially similar. For example, a DBR grating may comprise a plurality of repeat units 610, where each repeat unit 610 includes a plurality of phase grating elements and a plurality of a phase shifts. In some implementations, the number of phase grating elements is substantially the same (but not necessarily identical) in each of the plurality of repeat units 610. Additionally, or alternatively, the number and locations of the plurality of π phase shifts are substantially the same (but not necessarily identical) in each of the plurality of repeat units 610. In some implementations, a pair of DBRs (e.g., front mirror 604 and back mirror 606) may differ by a phase shift per repeat unit 610. For example, in a pair of DBR gratings, each DBR of the pair of DBRs has a different number of phase shifts per repeat unit 610 (e.g., resulting in a different number of peaks from each grating). In some implementations, the DBR of the pair of DBRs with the smaller repeat length has one less phase shift per repeat unit 610 (e.g., resulting in the mirror with the fewer number of peaks having a larger peak spacing). In some implementations, a wavelength tunable semiconductor laser may comprise a gain section 602, a phase section 608, and a pair of DBR gratings 604, 606 as described herein.

In some implementations, as described herein, a phase grating element may include one mask paired with one space, and a phase shift results from inserting an additional (unpaired) mask or an additional (unpaired) space between grating elements. The grating pitch may correspond to the length of the phase grating element, such that a phase grating element takes up two half-pitches, and a phase shift inserts an additional half-pitch. Accordingly, the number of grating half-pitches per repeat length is 2×N_{PG}+N_{PS}, where N_{PG} is the number of phase grating elements and N_{PS} is the number of phase shifts. Accordingly, an even number of phase shifts per repeat length results in an even number of grating half-pitches, and an odd number of phase shifts results in an odd number of grating half-pitches.

In some implementations, the phase shift may correspond to a tone inversion, such as M-S-M-S changing to S-M-S-M or vice versa, rather than insertion of an additional unitary S or M into a stream of (M-S-M-S). In this way, phase gratings can be constructed with an odd number of phase shifts per repeat unit that result in an even number of half-pitches. In this case, each successive repeat unit 610 may be the opposite tone rather than strictly identical. Similarly, repeat units 610 may be constructed with an even number of phase shifts and an odd number of half-pitches using the same technique. Accordingly, a phase grating can generally present a tone inversion between successive repeat units 610, where the original repeat unit followed by an inverted tone version of the repeat unit 610 may be considered a “super repeat unit” and/or two substantially similar and non-identical repeat units 610.

As indicated above, FIGS. 6A-6E are provided as examples. Other examples may differ from what is described with regard to FIGS. 6A-6E.

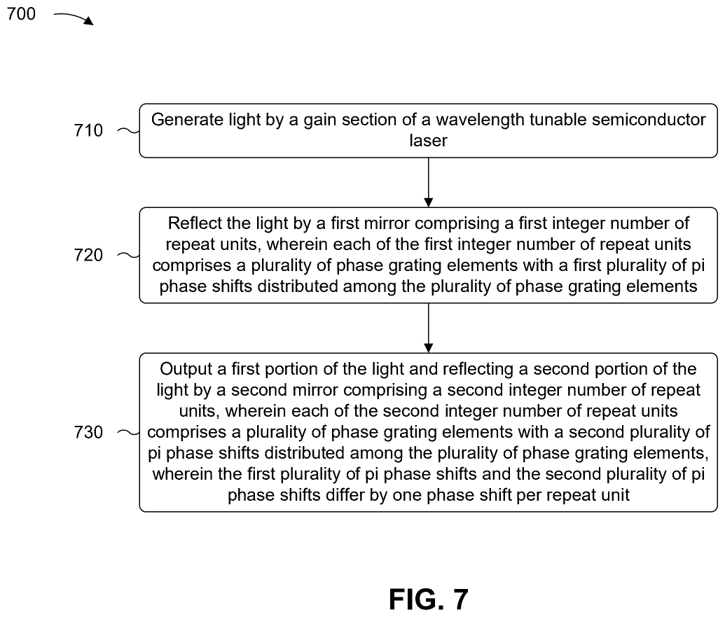

FIG. 7 illustrates an example process for operating a wavelength tunable laser. One or more process blocks of FIG. 7 are performed by a wavelength tunable semiconductor laser (e.g., Vernier-tuned DBR laser 600).

As shown in FIG. 7, process 700 includes generating light by a gain section of a wavelength tunable semiconductor laser (block 710). For example, the Vernier-tuned DBR laser 600 may include a gain section 602 configured to generate light, as described above.

As further shown in FIG. 7, process 700 includes reflecting the light by a first mirror comprising a first integer number of repeat units, wherein each of the first integer number of repeat units comprises a plurality of phase grating elements with a first plurality of pi phase shifts distributed among the plurality of phase grating elements (block 720). For example, the Vernier-tuned DBR laser 600 may include a back mirror 606 configured to reflect the light, where the back mirror 606 may comprise a first integer number of repeat units 610, each of which comprises a plurality of phase grating elements with a first plurality of pi phase shifts distributed among the plurality of phase grating elements, as described above.

As further shown in FIG. 7, process 700 includes outputting a first portion of the light and reflecting a second portion of the light by a second mirror comprising a second integer number of repeat units, wherein each of the second integer number of repeat units comprises a plurality of phase grating elements with a second plurality of pi phase shifts distributed among the plurality of phase grating elements, wherein the first plurality of pi phase shifts and the second plurality of pi phase shifts differ by one phase shift per repeat unit (block 730). For example, the Vernier-tuned DBR laser 600 may include a front mirror 604 configured to output a first portion of the light and reflect a second portion of the light, where the front mirror 604 comprises a second integer number of repeat units 610, each of which comprises a plurality of phase grating elements with a second plurality of pi phase shifts distributed among the plurality of phase grating elements, as described above. In some aspects, the first plurality of pi phase shifts and the second plurality of pi phase shifts differ by one phase shift per repeat unit.

Process 700 may include additional aspects, such as any single aspect or any combination of aspects described below and/or in connection with one or more other processes described elsewhere herein.

In a first aspect, process 700 includes adjusting, by a cavity optical length adjustment section (e.g., phase section 608) arranged between the gain section 602 and the front mirror 604 or the back mirror 606, an optical length of an optical cavity of the Vernier-tuned DBR laser 600 to adjust a refractive index of the optical cavity and modulate a longitudinal mode spectrum of light generated by the gain section 602.

In a second aspect, alone or in combination with the first aspect, the first integer number of repeat units 610 is different from the second integer number of repeat units 610.

In a third aspect, alone or in combination with one or more of the first and second aspects, the first plurality of pi phase shifts is one less than a number of the second plurality of pi phase shifts.

In a fourth aspect, alone or in combination with one or more of the first through third aspects, the plurality of phase grating elements in each of the first integer number of repeat units 610 and the second integer number of repeat units 610 comprise an unetched region paired with an etched region.

In a fifth aspect, alone or in combination with one or more of the first through fourth aspects, the first integer number of repeat units 610 further comprises a plurality of unetched regions.

In a sixth aspect, alone or in combination with one or more of the first through fifth aspects, the plurality of phase grating elements in the first integer number of repeat units 610 and the plurality of phase grating elements in the second integer number of repeat units 610 each include a first subset of phase grating elements having a first length and a second subset of phase grating elements having a second length that is longer than the first length, and the first plurality of pi phase shifts and the second plurality of pi phase shifts are each distributed among the second subset of phase grating elements having the second length.

In a seventh aspect, alone or in combination with one or more of the first through sixth aspects, the first integer number of repeat units 610 in the front mirror 604 are configured to produce a first comb reflection spectrum with a first plurality of reflection peaks within a target spectral envelope, the second integer number of repeat units 610 in the back mirror 606 are configured to produce a second comb reflection spectrum with a second plurality of reflection peaks within the target spectral envelope, and the first plurality of reflection peaks has one less reflection peak than the second plurality of reflection peaks.

In an eighth aspect, alone or in combination with one or more of the first through seventh aspects, the first comb reflection spectrum and the second comb reflection spectrum each further include one or more reflection peaks outside the target spectral envelope that are smaller than the first plurality of reflection peaks and the second plurality of reflection peaks within the target spectral envelope by at least five fold.

In a ninth aspect, alone or in combination with one or more of the first through eighth aspects, the first plurality of reflection peaks and the second plurality of reflection peaks within the target spectral envelope have a shape that compensates for a material-based spectrum of the gain section 602.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “front,” “back,” “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A wavelength tunable semiconductor laser, comprising:
a first mirror comprising a first integer number of repeat units, wherein each of the first integer number of repeat units comprises a plurality of phase grating elements with a first plurality of pi phase shifts distributed among the plurality of phase grating elements;
a second mirror comprising a second integer number of repeat units, wherein each of the second integer number of repeat units comprises a plurality of phase grating elements with a second plurality of pi phase shifts distributed among the plurality of phase grating elements; and
a gain section arranged between the first mirror and the second mirror,
wherein the first plurality of pi phase shifts and the second plurality of pi phase shifts differ by one phase shift per repeat unit.

2. The wavelength tunable semiconductor laser of claim 1, further comprising:
a cavity optical length adjustment section, arranged between the gain section and the second mirror or between the gain section and the first mirror, configured to adjust an optical length of an optical cavity of the wavelength tunable semiconductor laser to adjust a refractive index of the optical cavity and modulate a longitudinal mode spectrum of light generated by the gain section.

3. The wavelength tunable semiconductor laser of claim 1, wherein the first integer number of repeat units is different from the second integer number of repeat units.

4. The wavelength tunable semiconductor laser of claim 1, wherein the first plurality of pi phase shifts is one less than a number of the second plurality of pi phase shifts.

5. The wavelength tunable semiconductor laser of claim 1, wherein the plurality of phase grating elements in each of the first integer number of repeat units and the second integer number of repeat units comprise an unetched region paired with an etched region.

6. The wavelength tunable semiconductor laser of claim 1, wherein the first integer number of repeat units further comprises a plurality of unetched regions.

7. The wavelength tunable semiconductor laser of claim 1, wherein:
the plurality of phase grating elements in the first integer number of repeat units and the plurality of phase grating elements in the second integer number of repeat units each include a first subset of phase grating elements having a first length and a second subset of phase grating elements having a second length that is longer than the first length, and
the first plurality of pi phase shifts and the second plurality of pi phase shifts are each distributed among the second subset of phase grating elements having the second length.

8. The wavelength tunable semiconductor laser of claim 1, wherein:
the first integer number of repeat units in the first mirror are configured to produce a first comb reflection spectrum with a first plurality of reflection peaks within a target spectral envelope,
the second integer number of repeat units in the second mirror are configured to produce a second comb reflection spectrum with a second plurality of reflection peaks within the target spectral envelope, and
the first plurality of reflection peaks has one less reflection peak than the second plurality of reflection peaks.

9. The wavelength tunable semiconductor laser of claim 8, wherein the first comb reflection spectrum and the second comb reflection spectrum each further include one or more reflection peaks outside the target spectral envelope that are smaller than the first plurality of reflection peaks and the second plurality of reflection peaks within the target spectral envelope by at least five fold.

10. The wavelength tunable semiconductor laser of claim 8, wherein the first plurality of reflection peaks and the second plurality of reflection peaks within the target spectral envelope have a shape that compensates for a material-based spectrum of the gain section.

11. An optical device, comprising:
a first distributed Bragg reflector (DBR) grating comprising a first plurality of repeat units, wherein the first plurality of repeat units each comprise a plurality of phase grating elements and a plurality of pi phase shifts, wherein:
a number of phase grating elements is substantially the same in each of the plurality of repeat units of the first DBR grating, and
a number or a location of the plurality of pi phase shifts is substantially the same in each of the plurality of repeat units of the first DBR grating; and
a second DBR grating comprising a second plurality of repeat units, wherein the second plurality of repeat units each comprise a plurality of phase grating elements and a plurality of pi phase shifts, wherein:
a number of phase grating elements is substantially the same in each of the plurality of repeat units of the second DBR grating,
a number or a location of the plurality of pi phase shifts is substantially the same in each of the plurality of repeat units of the second DBR grating, and
the number of the plurality of pi phase shifts in each of the first plurality of repeat units of the first DBR grating is different from the number of the plurality of pi phase shifts in each of the second plurality of repeat units of the second DBR grating.

12. The optical device of claim 11, wherein a DBR gating, of the first DBR grating and the second DBR grating, with a smaller repeat length has one less phase shift per repeat unit relative to the other DBR gating.

13. The optical device of claim 11, further comprising:
a gain section between the first DBR grating and the second DBR grating.

14. A method, comprising:
generating light by a gain section of a wavelength tunable semiconductor laser;
reflecting the light by a first mirror comprising a first integer number of repeat units, wherein each of the first integer number of repeat units comprises a plurality of phase grating elements with a first plurality of pi phase shifts distributed among the plurality of phase grating elements; and
outputting a first portion of the light and reflecting a second portion of the light by a second mirror comprising a second integer number of repeat units, wherein each of the second integer number of repeat units comprises a plurality of phase grating elements with a second plurality of pi phase shifts distributed among the plurality of phase grating elements,
wherein the first plurality of pi phase shifts and the second plurality of pi phase shifts differ by one phase shift per repeat unit.

15. The method of claim 14, further comprising:
adjusting, by a cavity optical length adjustment section arranged between the gain section and the first mirror or between the gain section and the second mirror, a refractive index of an optical cavity of the wavelength tunable semiconductor laser to adjust a refractive index of the optical cavity and modulate a longitudinal mode spectrum of light generated by the gain section.

16. The method of claim 14, wherein the first integer number of repeat units is different from the second integer number of repeat units.

17. The method of claim 14, wherein the first plurality of pi phase shifts is one less than a number of the second plurality of pi phase shifts.

18. The method of claim 14, wherein the plurality of phase grating elements in each of the first integer number of repeat units and the second integer number of repeat units comprise an unetched region paired with an etched region.

19. The method of claim 14, wherein the first integer number of repeat units further comprises a plurality of unetched regions.

20. The method of claim 14, wherein:
the plurality of phase grating elements in the first integer number of repeat units and the plurality of phase grating elements in the second integer number of repeat units each include a first subset of phase grating elements having a first length and a second subset of phase grating elements having a second length that is longer than the first length, and
the first plurality of pi phase shifts and the second plurality of pi phase shifts are each distributed among the second subset of phase grating elements having the second length.

21. The method of claim 14, wherein:
the first integer number of repeat units in the first mirror are configured to produce a first comb reflection spectrum with a first plurality of reflection peaks within a target spectral envelope,
the second integer number of repeat units in the second mirror are configured to produce a second comb reflection spectrum with a second plurality of reflection peaks within the target spectral envelope, and
the first plurality of reflection peaks has one less reflection peak than the second plurality of reflection peaks.

22. The method of claim 21, wherein the first comb reflection spectrum and the second comb reflection spectrum each further include one or more reflection peaks outside the target spectral envelope that are smaller than the first plurality of reflection peaks and the second plurality of reflection peaks within the target spectral envelope by at least five fold.

23. The method of claim 21, wherein the first plurality of reflection peaks and the second plurality of reflection peaks within the target spectral envelope have a shape that compensates for a material-based spectrum of the gain section.
